(19) United States
(12) Patent Application Publication
(10) Pub. No.: US 2022/0308099 A1
(43) Pub. Date: Sep. 29, 2022

(54) SYSTEM AND METHOD FOR ANALYZING WAVEFORM APPLIED TO SERVO MOTOR SYSTEM

(71) Applicant: TECO Electric & Machinery Co., Ltd., TAIPEI CITY (TW)

(72) Inventors: Chia-Jen LIN, TAIPEI CITY (TW); Feng-Chieh LIN, TAIPEI CITY (TW); Chun-Chi LAI, TAIPEI CITY (TW); Chin-Sheng CHEN, TAIPEI CITY (TW)

(21) Appl. No.: 17/351,396

(22) Filed: Jun. 18, 2021

(30) Foreign Application Priority Data
Mar. 26, 2021 (TW) 110111032

(51) Int. Cl. G01R 19/25; G01R 13/02

(52) U.S. Cl. CPC G01R 19/2509; G01R 13/02; G01R 31/34

(57) ABSTRACT

A system for analyzing waveform, applied to a servo motor system, includes a data-acquiring module, a waveform-constructing module, a sampling module, a data-processing module, and a deep learning module. The present system retrieves normal data, abnormal date, and real-time data for generating a normal waveform, an abnormal waveform, and a real-time waveform, and then samples normal sampling data from the normal data, abnormal sampling data from the abnormal data, and real-time sampling data from the real-time data. The data-processing module is utilized to add the normal data and the abnormal data to form corresponding total data. The deep learning module utilizes a deep learning model to identify whether or not the real-time waveform is the normal waveform or the abnormal waveform by evaluating the normal waveform, the abnormal waveform and the total data.

This application claims the benefit of Taiwan Patent Application Serial No. 110111032, filed Mar. 26, 2021, the subject matter of which is incorporated herein by reference.

### BACKGROUND OF THE INVENTION

### (1) Field of the Invention

The invention relates to a system and method, and more particularly to a system and method for analyzing waveform applied to servo motor system.

### (2) Description of the Prior Art

The motor, also known as an electric motor, is one of popular electrical devices that can convert electrical energy into kinetic energy for driving the other devices. The principle of the motor and that of a generator are roughly the same, and the main difference in between lies in the style of energy conversion.

Among various applications of motors, a servo motor drive system, generally including a servo motor and an actuator, is widely applied to elevators, cranes, oil pumps and so on. In particular, the oil pump used for exploring oil and gas is one of important exemplary examples of the servo motor system, no matter where the exploration is on land or at sea. On the other hand, under long-term operations, the actuator would inevitably meet problems such as capacitor degradation, component damages and invasion of foreign matters. Eventually, the associated servo motor drive system would go wrong to induce some kinds of abnormality in machinery safety or comfort to specific fields, such as elevators and cranes. Now, speaking back to the issue of the oil pump for exploring oil and gas, if the servo motor drive system is shut down due to any abnormality, then daily gross loss would be probably up to USD140,000. Obviously, reliability and real-time detection diagnosis of the servo motor drive system become increasingly important.

### SUMMARY OF THE INVENTION

In view that, after long-term operations of the conventional servo motor drive system, several problems would meet inevitably, such as actuator problems, abnormality in the servo motor drive system and some other derivative problems, accordingly it is an object of the present invention to provide a system and method for analyzing waveform applied to servo motor system to resolve at least one of the aforesaid problems in the art.

In accordance with the present invention, a system for analyzing waveform applied to servo motor system, applied to a servo motor drive system, includes a data-acquiring module, a waveform-constructing module, a sampling module, a data-processing module and a deep learning module. The data-acquiring module is configured for receiving M normal operation data, M abnormal operation data and M real-time operation data from the servo motor drive system. The waveform-constructing module is configured for receiving the M normal operation data, the M abnormal operation data and the M real-time operation data, and further for constructing correspondingly a normal operation waveform, an abnormal operation waveform and a real-time operation waveform. The sampling module is configured for evaluating the normal operation waveform, the abnormal operation waveform and the real-time operation waveform to sample N normal-operation data sets, N abnormal-operation data sets and N real-time-operation data sets. Each of the N normal-operation data sets includes O normal-operation sampling data sampled from the M normal operation data, each of the N abnormal-operation data sets includes O abnormal-operation sampling data sampled from the M abnormal operation data, and each of the N real-time-operation data sets includes O real-time-operation sampling data sampled from the M real-time operation data, in which N<M and O<M. The data-processing module is configured for receiving the N normal-operation data sets and the N abnormal-operation data sets, and further for adding the N normal-operation data sets and the N abnormal-operation data sets in a set-to-set manner to form N total-operation data sets. The deep learning module is configured for receiving the normal operation waveform, the abnormal operation waveform and the N total-operation data sets to perform deep learning. When the deep learning is finished, the deep learning module receives and investigates the real-time operation waveform and the N real-time-operation data sets. When an abnormal state at the real-time operation waveform is detected, an abnormal-operation initial data set is located from the N real-time-operation data sets, and a corresponding alert signal is generated.

In one embodiment of the present invention, the data-acquiring module includes an analog-to-digital conversion unit for converting data formats of the M normal operation data, the M abnormal operation data and the M real-time operation data from analog formats into corresponding digital formats.

In one embodiment of the present invention, the data-acquiring module further includes a normalization unit electrically connected with the analog-to-digital conversion unit and configured for performing data normalization upon the M normal operation data, the M abnormal operation data and the M real-time operation data.

In one embodiment of the present invention, the data-acquiring module further includes a standardization unit electrically connected with the analog-to-digital conversion unit and configured for performing standardization upon the M normal operation data, the M abnormal operation data and the M real-time operation data.

In one embodiment of the present invention, the sampling module includes a window-sampling unit, the window-sampling unit utilizes a window to move along the normal operation waveform, the abnormal operation waveform or the real-time operation waveform so as to sample the O normal-operation sampling data, the O abnormal-operation sampling data or the O real-time-operation sampling data, respectively.

In one embodiment of the present invention, the sampling module further includes a window-setting unit electrically connected with the window-sampling unit and configured for manually setting a sampling width for the window.

In one embodiment of the present invention, the system for analyzing waveform applied to servo motor system further includes a display module electrically connected with the deep learning module and configured for displaying an abnormality information upon when the alert signal is received.

In one embodiment of the present invention, the deep learning module utilizes a deep learning model of convolution neural network to perform the deep learning.

In another aspect of the present invention, a method for analyzing waveform applied to servo motor system, performed by utilizing the aforesaid system for analyzing waveform applied to servo motor system, includes the steps of: utilizing the data-acquiring module to receive the M normal operation data, the M abnormal operation data and the M real-time operation data; utilizing the waveform-constructing module to receive the M normal operation data, the M abnormal operation data and the M real-time operation data from the data-acquiring module, and to construct correspondingly the normal operation waveform, the abnormal operation waveform and the real-time operation waveform; utilizing the data-processing module to receive the N normal-operation data sets and the N abnormal-operation data sets, and adding the N normal-operation data sets and the N abnormal-operation data sets in a set-to-set manner to form the N total-operation data sets; utilizing the deep learning module to receive the normal operation waveform, the abnormal operation waveform and the N total-operation data sets to perform the deep learning; and, utilizing the deep learning module to receive and investigate the real-time operation waveform and the N real-time-operation data sets, to locate the abnormal-operation initial data set upon when the real-time operation waveform is determined to be in the abnormal state, and then to generate correspondingly the alert signal.

In one embodiment of the present invention, the method for analyzing waveform applied to servo motor system further includes a step of utilizing a display module to display an abnormality information upon when the alert signal is received.

As stated above, in the system and method for analyzing waveform applied to servo motor system provided by the present invention, the data-acquiring module, the waveform-constructing module, the sampling module, the data-processing module and the deep learning module are included. In comparison to the prior art, the present invention utilizes the normal operation waveform, the abnormal operation waveform and the total-operation data sets to perform the deep learning, and the deep learning module investigates the real-time operation waveform for locating possible abnormality. While the abnormality is detected, the abnormal-operation initial data set is determined from the real-time-operation data sets so as to realize the instant abnormal state at the servo motor drive system, and thus the required maintenance, repair and treatment can be provided in time to turn the servo motor drive system back to the normal state. In addition, the present invention can further utilize the display module to display the abnormality information including at least the abnormal-operation initial data set, so that the instant abnormal state of the servo motor drive system can be determined immediately.

All these objects are achieved by the system and method for analyzing waveform applied to servo motor system described below.

### BRIEF DESCRIPTION OF THE DRAWINGS

The present invention will now be specified with reference to its preferred embodiment illustrated in the drawings, in which:

FIG. 1 is a schematic block view of a preferred embodiment of the system for analyzing waveform applied to servo motor system in accordance with the present invention;

FIG. 2 demonstrates schematically sampling of the sampling module upon a normal operation waveform in accordance with the present invention;

FIG. 3 demonstrates schematically an abnormal operation waveform constructed by the waveform-constructing module in accordance with the present invention;

FIG. 4 demonstrates schematically sampling of the sampling module upon an abnormal operation waveform in accordance with the present invention;

FIG. 5 demonstrates schematically deep learning performed by the deep learning module in accordance with the present invention;

FIG. 6 demonstrates schematically a real-time operation waveform constructed by the waveform-constructing module in accordance with the present invention;

FIG. 7 illustrates schematically abnormality information in accordance with the present invention; and

FIG. 8 is a schematic flowchart of a preferred embodiment of the method for analyzing waveform applied to servo motor system in accordance with the present invention.

### DESCRIPTION OF THE PREFERRED EMBODIMENT

The invention disclosed herein is directed to a system and method for analyzing waveform applied to servo motor system. In the following description, numerous details are set forth in order to provide a thorough understanding of the present invention. It will be appreciated by one skilled in the art that variations of these specific details are possible while still achieving the results of the present invention. In other instance, well-known components are not described in detail in order not to unnecessarily obscure the present invention.

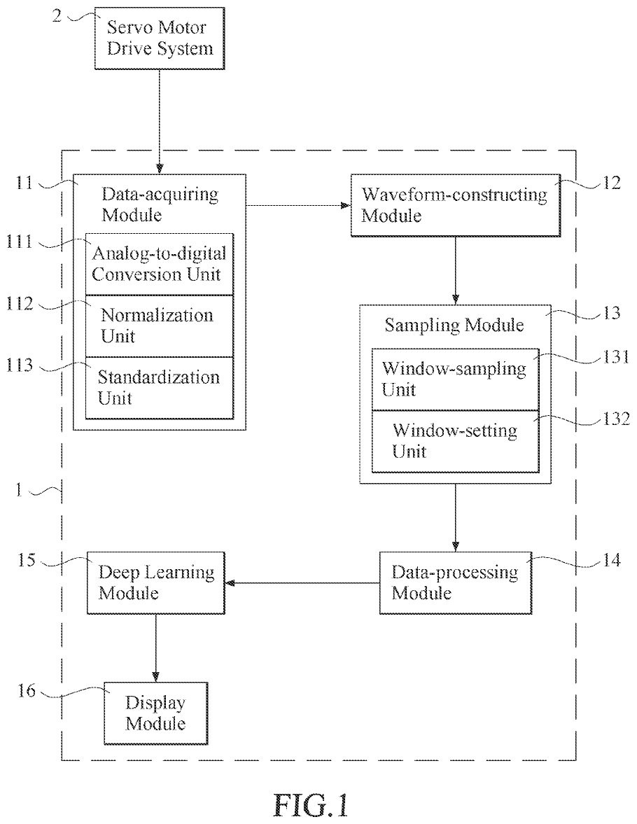

Referring to FIG. 1, a schematic block view of a preferred embodiment of the system for analyzing waveform applied to servo motor system in accordance with the present invention is shown. In this embodiment, the system for analyzing waveform applied to servo motor system 1, applied to a servo motor drive system 2, includes a data-acquiring module 11, a waveform-constructing module 12, a sampling module 13, a data-processing module 14 and a deep learning module 15. In addition, the system for analyzing waveform applied to servo motor system 1 further includes a display module 16. Generally, the servo motor drive system 2 includes a servo motor and an actuator, in which the actuator usually adopts a frequency converter. This frequency converter is a prior art, and thus detail thereabout is omitted herein.

The data-acquiring module 11, configured for receiving M normal operation data, M abnormal operation data and M real-time operation data captured from the servo motor drive system 2, includes an analog-to-digital conversion unit 111, a normalization unit 112 and a standardization unit 113.

The analog-to-digital conversion unit 111 is used to transform data formats of the received normal operation data, abnormal operation data and real-time operation data from original analog formats into corresponding digital formats.

The normalization unit 112, electrically connected with the analog-to-digital conversion unit 111, is used for performing data normalization upon the normal operation data, the abnormal operation data and the real-time operation data, so that following operations can be much easier. In this embodiment, the data normalization is one of popular data-processing means that modulates data into corresponding values between 0 and 1 without varying the associated distribution pattern of the data.

The standardization unit 113, similar to the normalization unit 112, is used for performing standardization upon the normal operation data, the abnormal operation data and the real-time operation data, so that following operations can be much easier. The standardization is one of popular statistic means that applies relevant formula to modulate data into corresponding values between 0 and 1 without varying the associated distribution pattern of the data.

It shall be explained that the standardization unit 113 and the normalization unit 112 follow almost similar steps for processing data. In this embodiment, though these two units are both included, yet such an example is only for concise explanation. Practically, according to the present invention, the system for analyzing image can simply include anyone of these two units 112, 113.

The waveform-constructing module 12 is used for receiving the M normal operation data, the M abnormal operation data and the M real-time operation data, and thereby for constructing correspondingly a normal operation waveform, an abnormal operation waveform and a real-time operation waveform.

The sampling module 13, electrically connected with the waveform-constructing module 12, is used for evaluating the normal operation waveform, the abnormal operation waveform and the real-time operation waveform to sample N normal-operation data sets and N abnormal-operation data sets and N real-time-operation data set, respectively. Each of the N normal-operation data sets includes O normal-operation sampling data sampled from the M normal operation data, each of the N abnormal-operation data sets includes O normal-operation sampling data sampled from the M normal operation data, and each of the N real-time-operation data sets includes O real-time operation sampling data sampled from the M real-time operation data, in which N<M and O<M. In this embodiment, the sampling module 13 further includes a window-sampling unit 131 and a window-setting unit 132.

The data-processing module 14 receives the normal-operation data sets and the abnormal-operation data sets, and further overlaps these two data sets by adding in a set-to-set manner so as to form a plurality of total-operation data sets.

The deep learning module 15 receives the normal operation waveform, the abnormal operation waveform and the total-operation data sets to then perform deep learning. After the deep learning is complete, the deep learning module 15 would receive and detect the real-time operation waveform and the real-time-operation data sets. As an abnormal state in the real-time operation waveform is confirmed, then an abnormal-operation initial data set would be determined among the N real-time-operation data sets, and thereupon an alert signal would be generated.

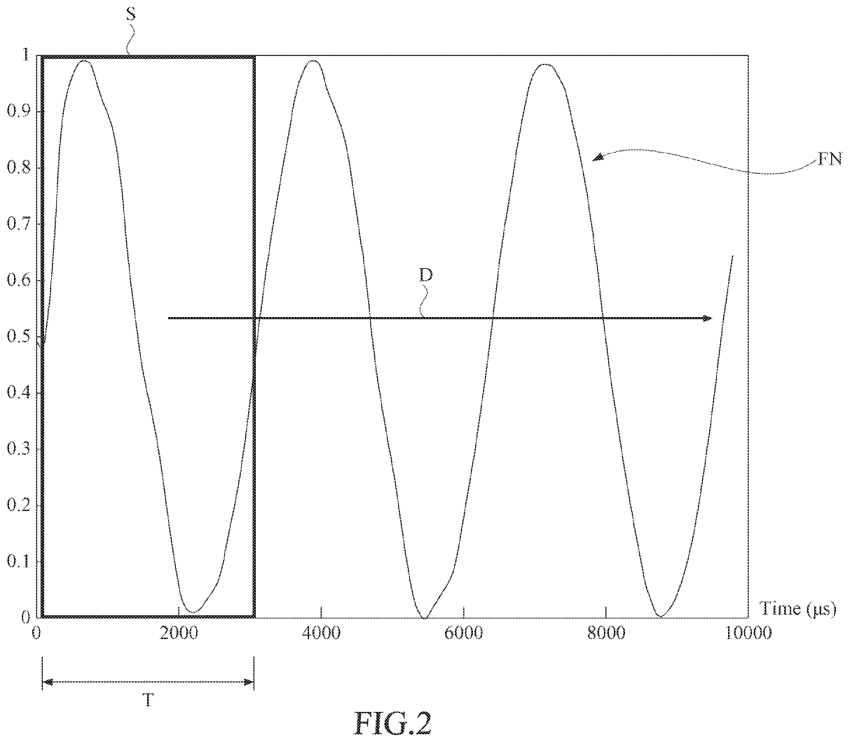

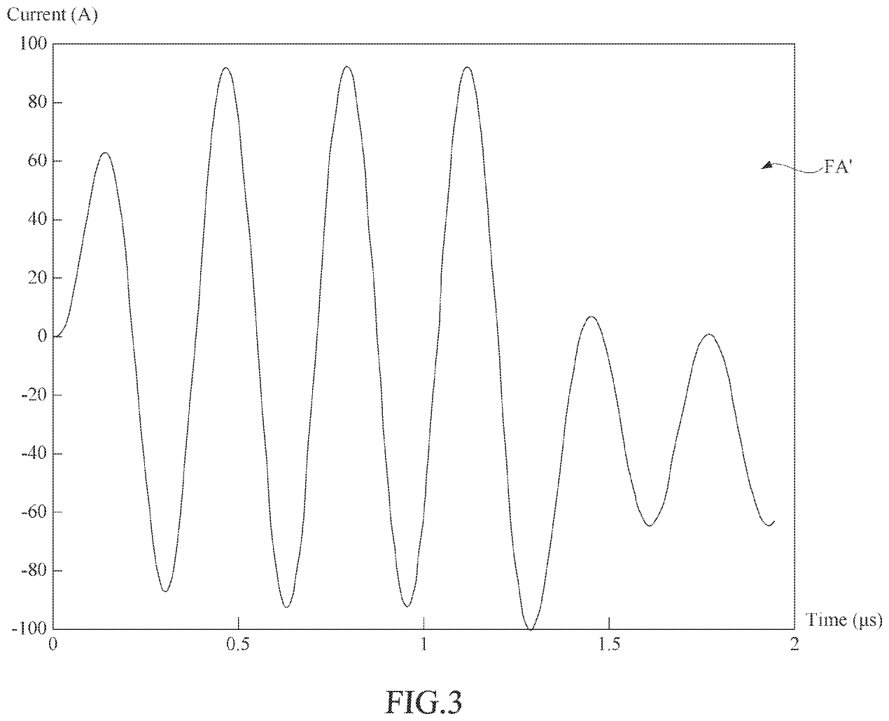

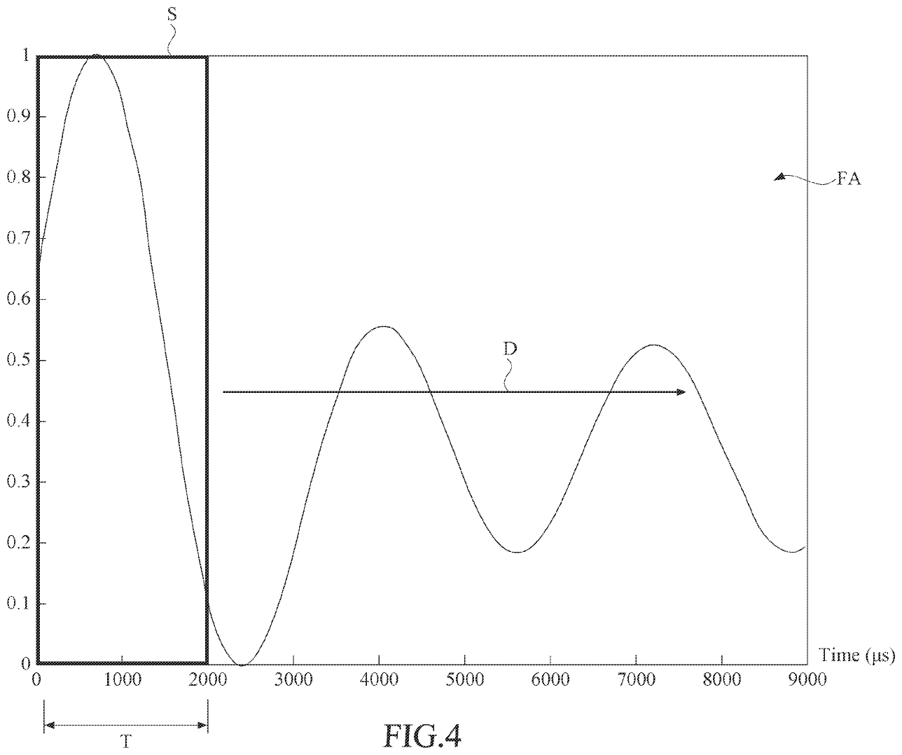

Then, refer to FIG. 1 through FIG. 4 together; where FIG. 2 demonstrates schematically sampling of the sampling module upon a normal operation waveform in accordance with the present invention, FIG. 3 demonstrates schematically an abnormal operation waveform constructed by the waveform-constructing module in accordance with the present invention, and FIG. 4 demonstrates schematically sampling of the sampling module upon an abnormal operation waveform in accordance with the present invention. As shown, the data-acquiring module 11 would receive M normal operation data and M abnormal operation data from the servo motor drive system 2. In the present invention, any of the normal operation data and the abnormal operation data can be realized as a voltage, a current or a modulated pulse width. In FIG. 3, the data therein are read as, but not limited to, the current values.

The waveform-constructing module 12 would evaluate the M normal operation data to construct the corresponding normal operation waveform. Preferably, if the M normal operation data are processed by data normalization or standardization to map the data into a 0- to 1 range, then the waveform-constructing module 12 would construct a normal operation waveform FN as shown in FIG. 2.

Similarly, the waveform-constructing module 12 would evaluate the M abnormal operation data to construct a corresponding abnormal operation waveform. If the M abnormal operation data are not processed by data normalization or standardization, then the waveform-constructing module 12 would construct an abnormal operation waveform FA′, as shown in FIG. 3. On the other hand, if the M abnormal operation data are already processed by the data normalization or standardization so as to be within 0 and 1, then the waveform-constructing module 12 would construct an abnormal operation waveform FA, as shown in FIG. 4.

Then, the sampling module 13 would introduce a window S upon the normal operation waveform FN and the abnormal operation waveform FA, and move the window S there-along in a sampling direction D so as to sample out the normal-operation sampling data and abnormal-operation sampling data, respectively. By having the normal operation waveform FN as an example, the window S would obtain one normal-operation data set in each sampling, and each of the normal-operation data sets would include a plurality of the normal-operation sampling data sampled from the M normal operation data. The window-setting unit 132 is configured for manually setting a sampling width T for the window S. Practically, the sampling width T would be set to one, a half or a quarter of the wave period.

Generally speaking, for sampling continuity, the total number of the normal-operation sampling data would be greater than that of the normal operation data. Mathematically, for example, the normal operation data can form a (9728×1) vector (i.e., M=9278), while the normal-operation sampling data can form a (3243×1298) matrix (i.e., N=1298, and O=3243). Please note that, in this embodiment, M, the raw data, is the number of the normal or real-time operation data, O is the number of the normal-operation or real-time-operation sampling data sampled from the M raw normal or real-time operation data, N is the number of the normal-operation or real-time-operation data sets, and each of the N sets includes O normal-operation or real-time-operation sampling data. In other words, according to this embodiment, the N data sets are formed by execute N times of sampling upon the M raw data, and each of the N sampling is to fetch a number N data from the M raw data. Definitely, each of the M raw data would be fetched repeatedly to some extent. As such, the (3243×1298) matrix (i.e., N=1298, and O=3243) can be formed from the (9728×1) vector (i.e., M=9278).

The data-processing module 14, electrically connected with the sampling module 13, is configured for receiving the normal-operation data sets and the abnormal-operation data sets, and further overlapping these two data sets by adding in a set-to-set manner so as to form a plurality of total-operation data sets. It shall be explained that all the total-operation data sets are consisted of all the normal-operation data sets and all the abnormal-operation data sets; namely, all the normal-operation sampling data and all the abnormal-operation sampling data. Mathematically, for example, the normal-operation sampling data can form a (3243×1298) matrix, while the normal-operation sampling data can form a (3243×1298) matrix, the abnormal-operation sampling data can form another (3243×1298) matrix, and the total operation data would be a (3243×2596) matrix. Namely, the number of the total-operation data sets is 2596; i.e., the sum of the number of the normal-operation data sets (N) and that of the abnormal-operation data sets (N).

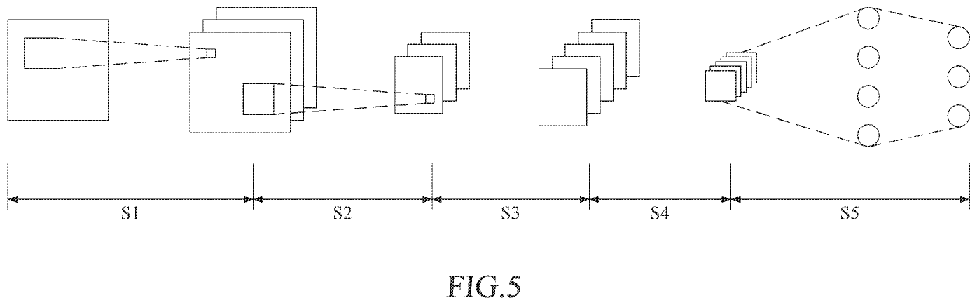

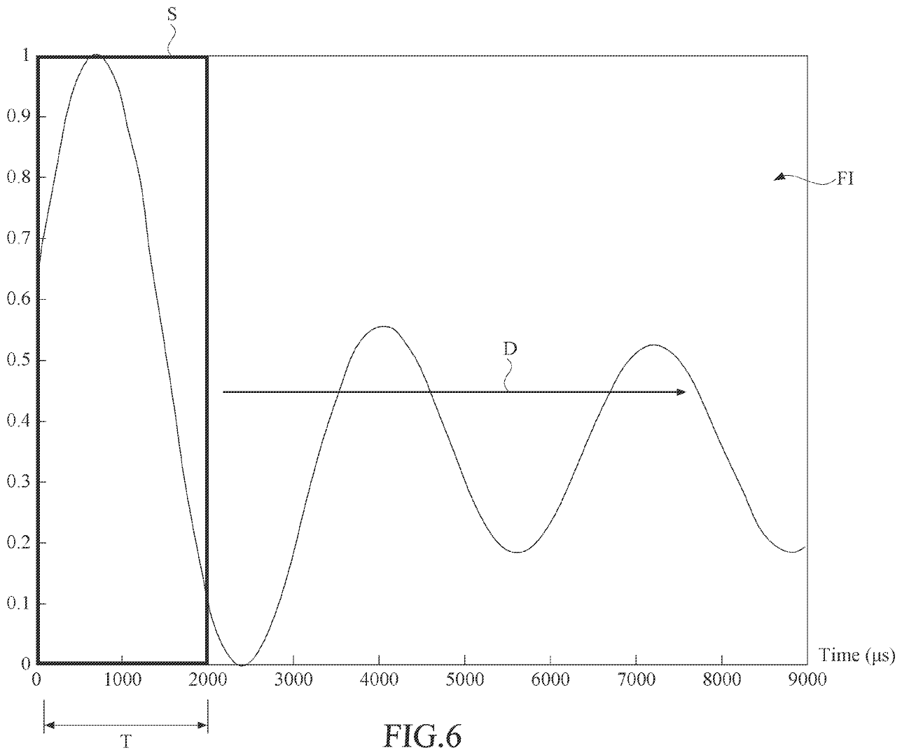

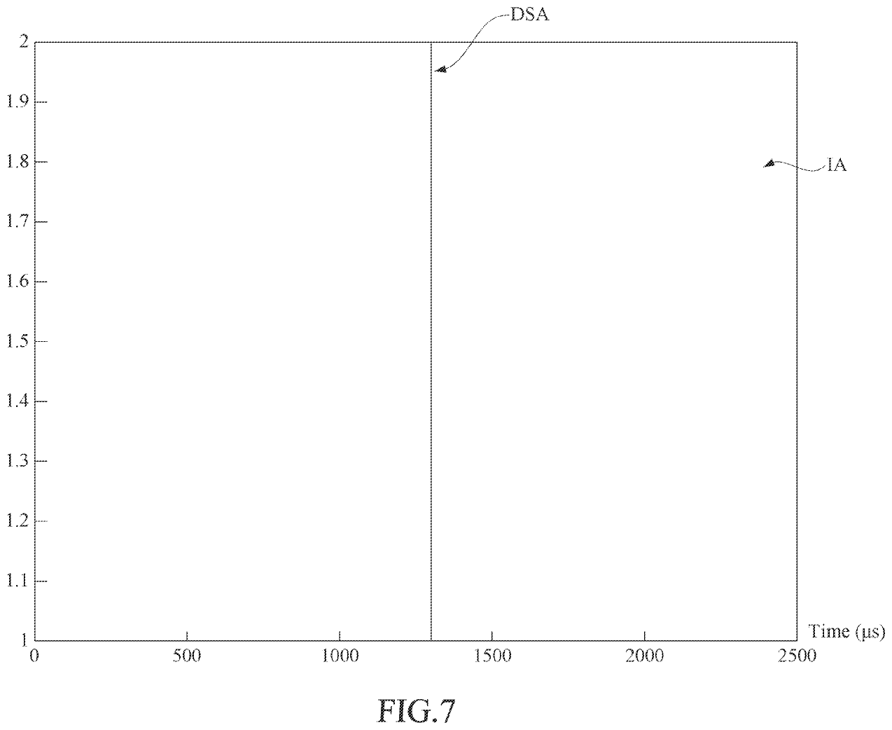

Then, refer to FIG. 5 through FIG. 7 together; where, FIG. 5 demonstrates schematically deep learning performed by the deep learning module in accordance with the present invention, FIG. 6 demonstrates schematically a real-time operation waveform constructed by the waveform-constructing module in accordance with the present invention, and FIG. 7 illustrates schematically abnormality information in accordance with the present invention. As shown, the deep learning module 15 is to receive the normal operation waveform, the abnormal operation waveform and the total-operation data sets for performing the deep learning.

The deep learning module 15 is to utilize a convolution neural network (CNN) training model for performing the deep learning.

In a first stage S1 of the deep learning, convolution is performed. In a second stage S2, pooling is performed. In this embodiment, the deep learning module 15 would use a rectified linear unit (ReLU) function as an activation function to connect the layers in series. In this embodiment, the convolution, the calculation of the ReLU function, and the pooling can be treated as an operation set. This operation set can be repeated several times. As shown in FIG. 5, this operation set is repeated twice (the second time is executed in the third stage S3 and the fourth stage S4) so as to complete the learning. That is, the normal operation waveform and the abnormal operation waveform provided to the deep learning module 15 would pass orderly through a convolution layer, a pooling layer, another convolution layer and another pooling layer, and then reach a fully connected layer; i.e., the fifth stage S5. Finally, the deep learning module 15 would have the Softmax software to determine a timing for generate necessary signals, and associated results would be outputted.

Though the foregoing section describes briefly the deep learning performed by the deep learning module 15 through the CNN training model, yet such a process shall be then understood to the skill in the art, and thus details thereabout would be omitted herein. In addition, the skill in the art shall be also realize that the present invention is not limited to adopt the CNN training model for deep learning. Practically, any other neural network model that can perform sorting automatically can is applicable for the present invention.

After the aforesaid training, the deep learning module 15 would receive and investigate the real-time operation waveform FI, as shown in FIG. 6. The data-acquiring module 11, the waveform-constructing module 12 and the sampling module 13 would then follow the aforesaid procedures to receive the real-time operation data, to construct the corresponding real-time operation waveform FI, and to sample the real-time-operation data sets containing the real-time-operation sampling data. Since these procedures have been described in the foregoing sections, and thus details thereabout would be omitted herein. The deep learning module 15 would perform investigation upon the real-time operation waveform FI, and sort out a percentage thereof for the normal operation waveform (such as the normal operation waveform FN shown in FIG. 2) and that for the abnormal operation waveform (such as the abnormal operation waveform FA shown in FIG. 4), so that the real-time operation waveform FI can be realized.

As the deep learning module 15 determines that the real-time operation waveform FI is the abnormal operation waveform, then it implies that the real-time operation waveform FI is in an abnormal state. In other words, the servo motor drive system 2 is currently in the abnormal state. Then, the deep learning module 15 would further determine an abnormal-operation initial data set DSA among the real-time-operation data sets (as shown in FIG. 7), and generate a corresponding alert signal. The abnormal-operation initial data set DSA is the data set where the abnormality is initiated. Since the servo motor drive system 2 is then in the abnormal state, thus all the following real-time-operation data sets would be abnormal as well. Hence, the deep learning module 15 can judge the abnormal-operation initial data set DSA when and where the abnormality begins. For example, if the 1298-th set among the real-time-operation data sets is the first abnormal set, then the deep learning module 15 would determine the 1298-th set of the real-time-operation data sets to be the abnormal-operation initial data set DSA.

In this embodiment, the display module 16 would receive the alert signal, and then display one corresponding abnormality information IA. According to this embodiment, the abnormality information IA includes at least the aforesaid abnormal-operation initial data set DSA, but not limited thereto. For example, the abnormality information IA can also include the real-time operation waveform FI. Accordingly, the abnormal state at the servo motor drive system 2 can be detected in a real-time manner through the abnormality information IA, and thus the corresponding abnormal-operation initial data set DSA can be immediately located. Therefore, necessary maintenance, diagnosis and repair can be performed in time to quickly turn the servo motor drive system 2 back into the normal operation state.

It shall be explained that the real-time operation waveform FI of FIG. 6 is the same as the abnormal operation waveform FA of FIG. 4. Thus, the deep learning module 15 would generate the alert signal. If the real-time operation waveform FI of FIG. 6 and the normal operation waveform FN of FIG. 2 are the same (thus, classified as the normal operation waveform), then the deep learning module 15 would not generate the alert signal.

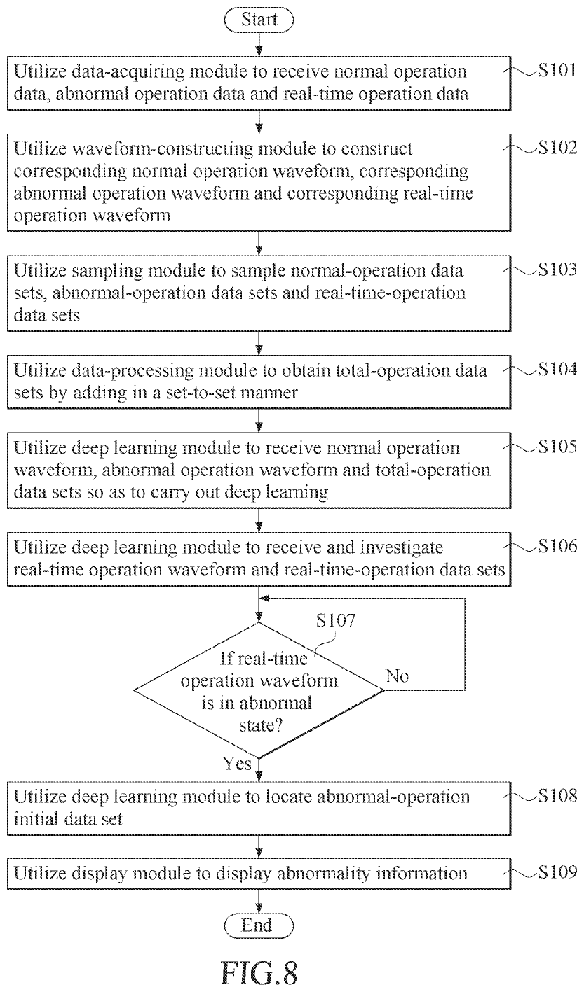

Finally, referring to FIG. 8, a schematic flowchart of a preferred embodiment of the method for analyzing waveform applied to servo motor system in accordance with the present invention is shown. In this embodiment, the method for analyzing waveform applied to servo motor system is performed by utilizing the system for analyzing waveform applied to servo motor system 1 of FIG. 1, and includes Step S101 to Step S109 as follows.

Step S101: Utilize the data-acquiring module to receive the normal operation data, the abnormal operation data and the real-time operation data.

Step S102: Utilize the waveform-constructing module to construct the corresponding normal operation waveform, the corresponding abnormal operation waveform and the corresponding real-time operation waveform.

Step S103: Utilize the sampling module to sample the normal-operation data sets, the abnormal-operation data sets and the real-time-operation data sets.

Step S104: Utilize the data-processing module to obtain the total-operation data sets by adding the normal-operation data sets and the abnormal-operation data sets in a set-to-set manner.

Step S105: Utilize the deep learning module to receive the normal operation waveform, the abnormal operation waveform and the total-operation data sets so as to carry out the deep learning.

Step S106: Utilize the deep learning module to receive and investigate the real-time operation waveform and the real-time-operation data sets.

Step S107: Determine whether or not the real-time operation waveform is in the abnormal state.

If positive, then go to Step S108. Otherwise, if negative, then repeat Step S107.

Step S108: Utilize the deep learning module to locate the abnormal-operation initial data set among the real-time-operation data sets.

Step S109: Utilize the display module to display the abnormality information.

Since contents of each step of the method for analyzing waveform applied to servo motor system have been elucidated in the previous sections, thus details thereabout would be omitted herein.

In summary, in the system and method for analyzing waveform applied to servo motor system provided by the present invention, the data-acquiring module, the waveform-constructing module, the sampling module, the data-processing module and the deep learning module are included. In comparison to the prior art, the present invention utilizes the normal operation waveform, the abnormal operation waveform and the total-operation data sets to perform the deep learning, and the deep learning module investigates the real-time operation waveform for locating possible abnormality. While the abnormality is detected, the abnormal-operation initial data set is determined from the real-time-operation data sets so as to realize the instant abnormal state at the servo motor drive system, and thus the required maintenance, repair and treatment can be provided in time to turn the servo motor drive system back to the normal state. In addition, the present invention can further utilize the display module to display the abnormality information including at least the abnormal-operation initial data set, so that the instant abnormal state of the servo motor drive system can be determined immediately.

While the present invention has been particularly shown and described with reference to a preferred embodiment, it will be understood by those skilled in the art that various changes in form and detail may be without departing from the spirit and scope of the present invention.

What is claimed is:

1. A system for analyzing waveform applied to servo motor system, applied to a servo motor drive system, comprising:
a data-acquiring module, configured for receiving M normal operation data, M abnormal operation data and M real-time operation data from the servo motor drive system;
a waveform-constructing module, configured for receiving the M normal operation data, the M abnormal operation data and the M real-time operation data, and further for constructing correspondingly a normal operation waveform, an abnormal operation waveform and a real-time operation waveform;
a sampling module, configured for evaluating the normal operation waveform, the abnormal operation waveform and the real-time operation waveform to sample N normal-operation data sets, N abnormal-operation data sets and N real-time-operation data sets, each of the N normal-operation data sets including O normal-operation sampling data sampled from the M normal operation data, each of the N abnormal-operation data sets including O abnormal-operation sampling data sampled from the M abnormal operation data, each of the N real-time operation data sets including O real-time-operation sampling data sampled from the M real-time operation data, N<M, O<M;
a data-processing module, configured for receiving the N normal-operation data sets and the N abnormal-operation data sets, and further for adding the N normal-operation data sets and the N abnormal-operation data sets in a set-to-set manner to form N total-operation data sets; and
a deep learning module, configured for receiving the normal operation waveform, the abnormal operation waveform and the N total-operation data sets to perform deep learning; wherein, when the deep learning is finished, the deep learning module receives and investigates the real-time operation waveform and the N real-time-operation data sets; wherein, when an abnormal state at the real-time operation waveform is detected, an abnormal-operation initial data set is located from the N real-time-operation data sets, and a corresponding alert signal is generated.

2. The system for analyzing waveform applied to servo motor system of claim 1, wherein the data-acquiring module includes an analog-to-digital conversion unit for converting data formats of the M normal operation data, the M abnormal operation data and the M real-time operation data from analog formats into corresponding digital formats.

3. The system for analyzing waveform applied to servo motor system of claim 2, wherein the data-acquiring module further includes a normalization unit electrically connected with the analog-to-digital conversion unit and configured for performing data normalization upon the M normal operation data, the M abnormal operation data and the M real-time operation data.

4. The system for analyzing waveform applied to servo motor system of claim 2, wherein the data-acquiring module further includes a standardization unit electrically connected with the analog-to-digital conversion unit and configured for performing standardization upon the M normal operation data, the M abnormal operation data and the M real-time operation data.

5. The system for analyzing waveform applied to servo motor system of claim 1, wherein the sampling module includes a window-sampling unit, the window-sampling unit utilizes a window to move along the normal operation waveform, the abnormal operation waveform or the real-time operation waveform so as to sample the O normal-operation sampling data, the O abnormal-operation sampling data or the O real-time-operation sampling data, respectively.

6. The system for analyzing waveform applied to servo motor system of claim 5, wherein the sampling module further includes a window-setting unit electrically connected with the window-sampling unit and configured for manually setting a sampling width for the window.

7. The system for analyzing waveform applied to servo motor system of claim 1, further including a display module electrically connected with the deep learning module and configured for displaying an abnormality information upon when the alert signal is received.

8. The system for analyzing waveform applied to servo motor system of claim 1, wherein the deep learning module utilizes a deep learning model of convolution neural network to perform the deep learning.

9. A method for analyzing waveform applied to servo motor system, performed by utilizing the system for analyzing waveform applied to servo motor system of claim 1, comprising the steps of:
(a) utilizing the data-acquiring module to receive the M normal operation data, the M abnormal operation data and the M real-time operation data;
(b) utilizing the waveform-constructing module to receive the M normal operation data, the M abnormal operation data and the M real-time operation data from the data-acquiring module, and to construct correspondingly the normal operation waveform, the abnormal operation waveform and the real-time operation waveform;
(c) utilizing the data-processing module to receive the N normal-operation data sets and the N abnormal-operation data sets, and adding the N normal-operation data sets and the N abnormal-operation data sets in a set-to-set manner to form the N total-operation data sets;
(d) utilizing the deep learning module to receive the normal operation waveform, the abnormal operation waveform and the N total-operation data sets to perform the deep learning; and
(e) utilizing the deep learning module to receive and investigate the real-time operation waveform and the N real-time-operation data sets, to locate the abnormal-operation initial data set upon when the real-time operation waveform is determined to be in the abnormal state, and then to generate correspondingly the alert signal.

10. The method for analyzing waveform applied to servo motor system of claim 9, further including a step of: (f) utilizing a display module to display an abnormality information upon when the alert signal is received.
